(19) United States
(12) Patent Application Publication
(10) Pub. No.: US 2024/0413094 A1
(43) Pub. Date: Dec. 12, 2024

(54) SEMICONDUCTOR DIE SHIELDING STRUCTURE

(71) Applicant: Cypress Semiconductor Corporation, San Jose, CA (US)

(72) Inventors: Thorsten MEYER, Regensburg (DE); Ludwig HEITZER, Falkenfels (DE); Clive O'DELL, HORLEY (GB); Mark PAVIER, EAST GRINSTEAD (GB); Paul WESTMARLAND, Surrey (GB)

(21) Appl. No.: 18/206,449

(22) Filed: Jun. 6, 2023

(51) Int. Cl. H01L 23/552; H01L 21/56; H01L 23/00; H01L 23/29; H01L 23/31; H01L 23/498; H01L 25/16

(52) U.S. Cl. CPC H01L 23/552; H01L 21/56; H01L 23/293; H01L 23/3107; H01L 23/3171; H01L 23/49811; H01L 24/24; H01L 25/165; H01L 2224/24265

(57) ABSTRACT

One or more structures and/or methods are provided. In an example of the subject matter presented herein, an apparatus includes a circuit board substrate. A package comprising a semiconductor die and a redistribution layer over the semiconductor die is mounted to the circuit board substrate. A first component is mounted to the redistribution layer over the semiconductor die. A shielding structure is mounted to the circuit board substrate over the package and the first component.

### BACKGROUND

In device packages, a footprint of a package is determined by the components mounted to a printed circuit board and any shielding provided for the components. For example, components in a device, such as oscillators, transistors, or other components, may generate electromagnetic interference that may affect the operation of other components, such as a semiconductor die. To reduce the effect of the electromagnetic interference, a shielding structure may be provided between the electromagnetic interference generating components and the components affected by the electromagnetic interference, and the shielding structure may be included within the package footprint.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

According to some embodiments, an apparatus, comprises a circuit board substrate, a package comprises a semiconductor die and a redistribution layer over the semiconductor die mounted to the circuit board substrate, a first component mounted to the redistribution layer over the semiconductor die, and a shielding structure mounted to the circuit board substrate over the package and the first component.

According to some embodiments, the package comprises a molding layer adjacent the semiconductor die, and a passivation layer over the molding layer and the semiconductor die, wherein the redistribution layer is at least partially embedded in the passivation layer, the package comprises a material region embedded in the molding layer under a portion of the wire bond contacting the redistribution layer, and the material region comprises a first material stiffer than a second material of the passivation layer.

According to some embodiments, a method, comprises mounting a package comprises a semiconductor die and a redistribution layer over the semiconductor die to a circuit board substrate, mounting a first component to the redistribution layer over the semiconductor die, and mounting a shielding structure to the circuit board substrate over the package and the first component.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIGS. 1A-1G are cross section diagrams of a device during various stages of manufacturing, in accordance with some embodiments.

FIGS. 2A-21 are cross section diagrams of a device during various stages of manufacturing, in accordance with some embodiments.

FIG. 3 is a flow diagram illustrating an example method for fabricating a device, in accordance with some embodiments.

FIGS. 4A-4G are cross section diagrams of a device during various stages of manufacturing, in accordance with some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

It is to be understood that the following description of embodiments is not to be taken in a limiting sense. The scope of the present disclosure is not intended to be limited by the embodiments described hereinafter or by the drawings, which are taken to be illustrative only. The drawings are to be regarded as being schematic representations and elements illustrated in the drawings are not necessarily shown to scale. Rather, the various elements are represented such that their function and general purpose become apparent to a person skilled in the art.

All numerical values within the detailed description and the claims herein are modified by “about” or “approximately” the indicated value, and take into account experimental error and variations that would be expected by a person having ordinary skill in the art.

In device packages, the package footprint is determined by the components mounted to a printed circuit board and any shielding structures provided for the components. Such shielding structures can increase the footprint of the device package. According to some embodiments, a redistribution layer is formed over a semiconductor die and components are mounted above the redistribution layer. In some embodiments, a shielding structure is formed over the components and the semiconductor die. Placing components vertically over the semiconductor die reduces the horizontal footprint of the shielding structure and the overall footprint of the package. An antenna may be provided outside the shielding structure to avoid interference between the electromagnetic signals generated by the antenna and the operation of the semiconductor die or components. In some embodiments, wire bonding is used to connect the semiconductor die to a circuit board substrate. The semiconductor die pre-package may be modified to increase stiffness at the wire bonding sites, such as by extending the redistribution layer through the passivation layer or by embedding a stiff material in the passivation layer to facilitate improved reliability wire bonding.

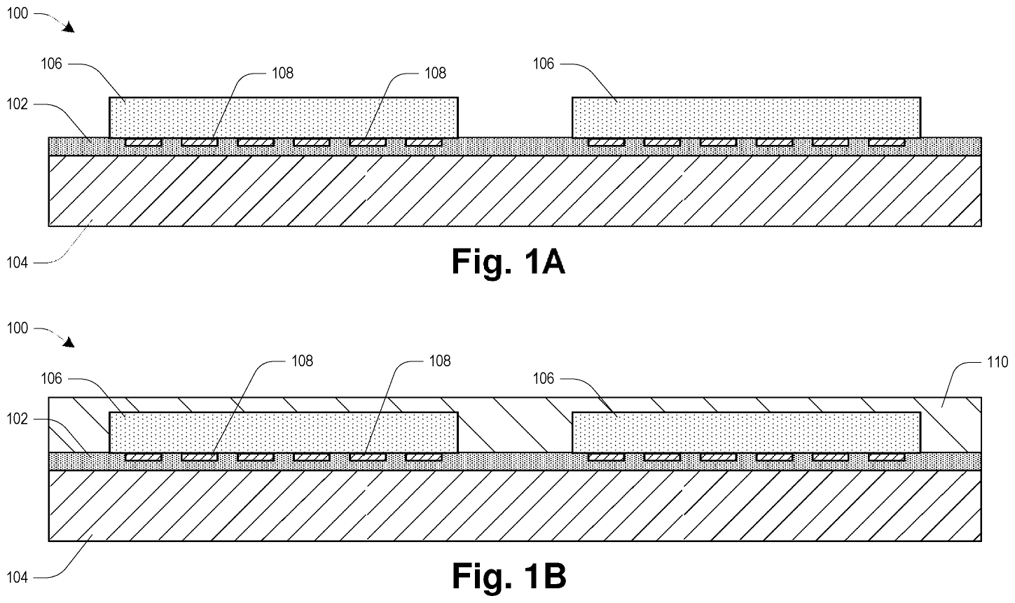

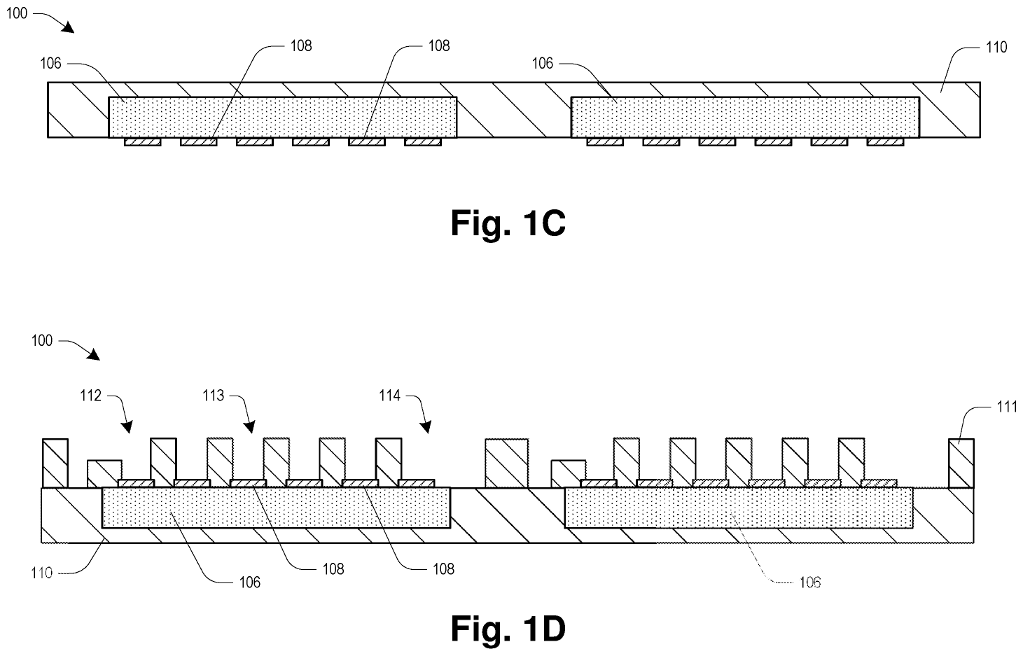

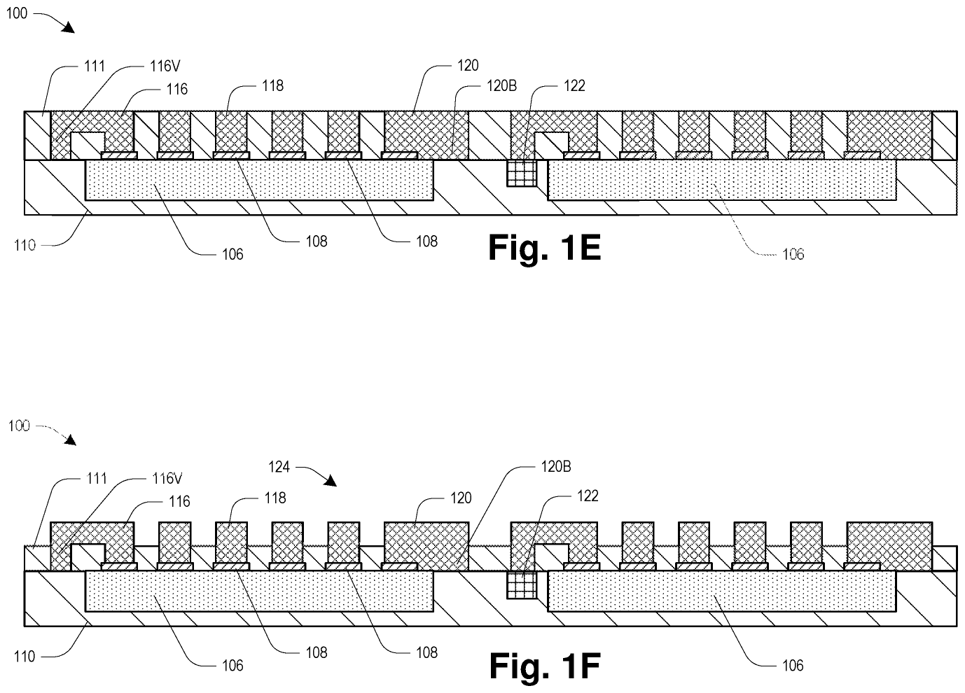

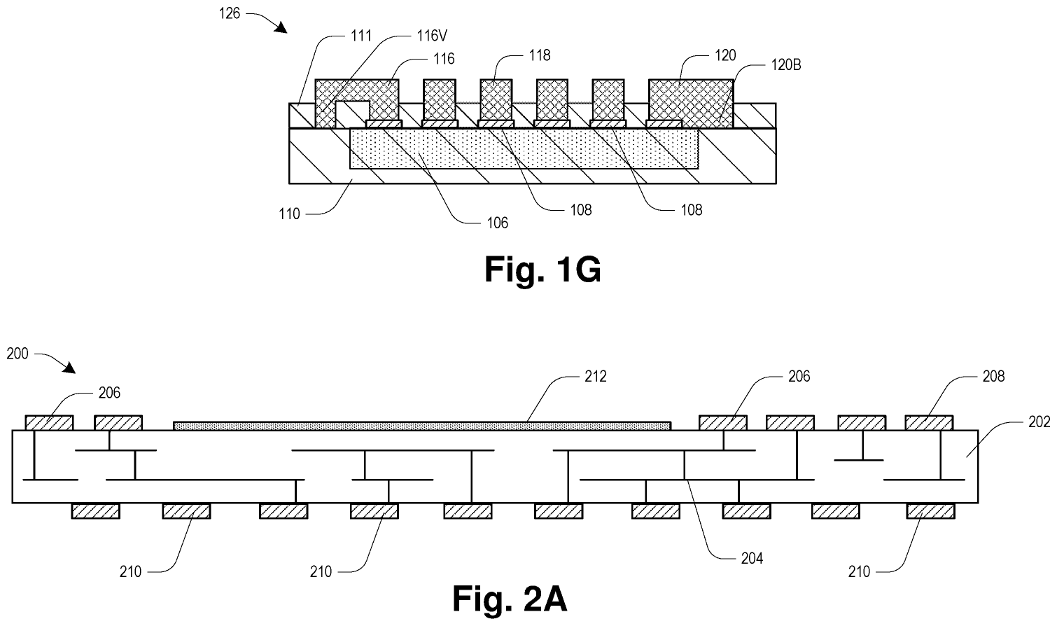

FIGS. 1A-1G are cross-section views of a device 100 during various stages of manufacturing, in accordance with some embodiments. Referring to FIG. 1A, the device 100 is assembled by forming an adhesion layer 102 over a mold carrier 104 and mounting semiconductor dies 106 to the adhesion layer 102. The semiconductor dies 106 comprise contact pads 108. A pick and place operation may be used to place the semiconductor dies 106. In some embodiments, the semiconductor dies 106 include wireless communication circuitry, such as circuitry for enabling Bluetooth communication. The adhesion layer may be an adhesive tape and/or comprise one or more layers of adhesive material(s). The adhesion layer may be attached to a carrier.

Referring to FIG. 1B, a molding layer 110 is formed over the semiconductor dies 106 and the adhesion layer 102, in accordance with some embodiments. The molding layer 110 may be formed by a compression molding process using an epoxy molding compound.

Referring to FIG. 1C, the adhesion layer 102 and the molding carrier 104 are removed, in accordance with some embodiments. For example, a heating process or other form of adding energy (e.g., chemical or mechanical) may be used to release the adhesion layer 102 from the semiconductor dies 106 and the molding layer 110, thereby exposing the contact pads 108 on the semiconductor dies 106.

Referring to FIG. 1D, the device 100 is inverted and a patterned passivation layer 111 is formed over the semiconductor dies 106 and the molding layer 110, in accordance with some embodiments. The patterned passivation layer 111 may be formed by depositing a dielectric material, such as polyimide, over the semiconductor dies 106 and the molding layer 110 and patterning the dielectric material using one or more lithography processes to define openings 112, 113, 114 in the dielectric material over the die pad positions. One or more curing processes may be performed on the dielectric material. A low temperature curing dielectric material may be used to avoid degrading the mold compound material during the curing process. The dielectric material may also cover the interfaces between chip and mold compound as well as the fan-out (mold compound) area.

Referring to FIG. 1E, contact structures 116, 118, 120 are formed in the openings 112, 113, 114. In some embodiments, thin film technology may be used to attach the semiconductor dies 106 to a redistribution layer and to provide landing pads on the dielectric layer or fan-out area. To form the metal redistribution layer, a seed layer is applied first, typically by sputtering. The seed layer may include multiple layers, such as a barrier layer (e.g., Cr, Ti or TiW with a thickness of approximately 50 nm) and a plating layer (e.g., Cu with a thickness of approximately 150 nm). A plating resist is applied over the seed layer and is structured using photolithography. After development, the plating resist is opened at the positions where the metallization layer is to be applied. Electro-plating may be used for adding material (e.g., Cu or metal stacks like CuNiAu) in the openings of the resist. The thickness of the electroplated layer may be 7 μm to 15 μm or even thicker. After metal plating (e.g., Cu/CuNiAu), the plating resist is removed and the seed layer is etched in two etching steps (Cu first, barrier layer second). This technique connects the semiconductor dies 106 to wire bonding sites or landing pads for attachment of passive or active components. Other structures and/or configurations of the contact structures 116, 118, 120 are within the scope of the present disclosure. For example, the number and arrangement of contact structures 116, 118, 120 may vary.

In some embodiments, one or more of the contact structures 116, 118, 120 may be directly attached to the molding layer 110 without a dielectric layer in between. Also, stiff material, like silicon or ceramic, may be embedded in the molding layer 110 at the wire bonding sites. These approaches increase the vertical stiffness at wire bonding sites. Otherwise the passivation layer 111 may deform during the wire bonding process, reducing the reliability of the wire bonds. In some embodiments, the passivation layer 111 is patterned to form a deeper portion in the recess 112 at the wire bonding sites such that the contact structure 116 includes a via portion 116V. In some embodiments, the passivation layer 111 is patterned to extend the recess 114 to remove the passivation layer over the edge of the semiconductor die 106 and over the molding layer 110 such that the contact structure 120 includes a base portion 120B that contacts the semiconductor die 106 and the molding layer 110.

In some embodiments, a material region 122 comprising a material having a stiffness greater than a material of the passivation layer 111 is embedded in the molding layer 110 prior to the patterning of the passivation layer 111 to increase vertical stiffness at the wire bonding sites. The material region 122 may comprise silicon, a ceramic, or some other stiff material compared to the material of the passivation layer 111.

Referring to FIG. 1F, the passivation layer 111 is recessed, in accordance with some embodiments. In some embodiments, the passivation layer 111 is recessed using an etch process. The contact structures 116, 118, 120 define a redistribution layer 124 over the associated semiconductor die 106. The redistribution layer 124 may be a fan-out redistribution layer (as illustrated) or a fan-in redistribution layer. The via portion 116V and/or the base portion 120B are extensions of the redistribution layer 124 that contact the molding layer 110 and comprise material stiffer than the material of the passivation layer 111 to increase vertical stiffness at wire bonding sites.

Referring to FIG. 1G, the semiconductor dies 106 and associated redistribution layers 124 are separated, in accordance with some embodiments. For example, a dicing process may be formed using a saw to singulate the semiconductor dies 106 to form a device pre-package 126.

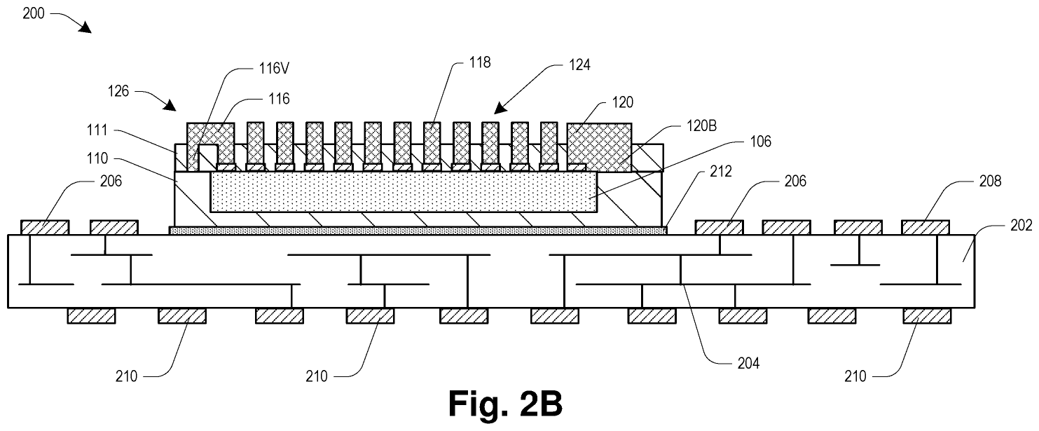

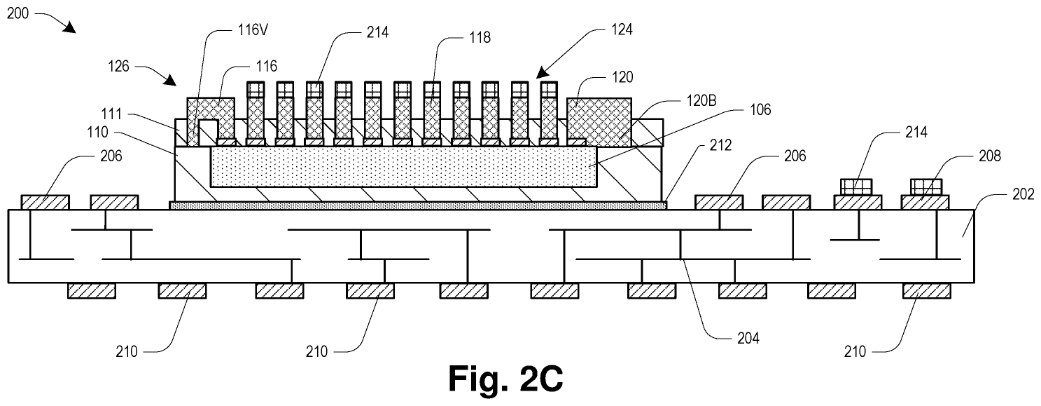

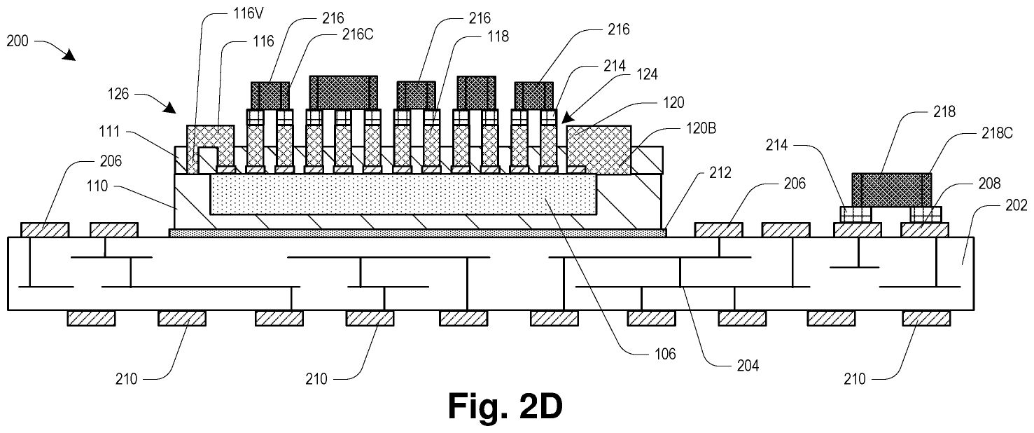

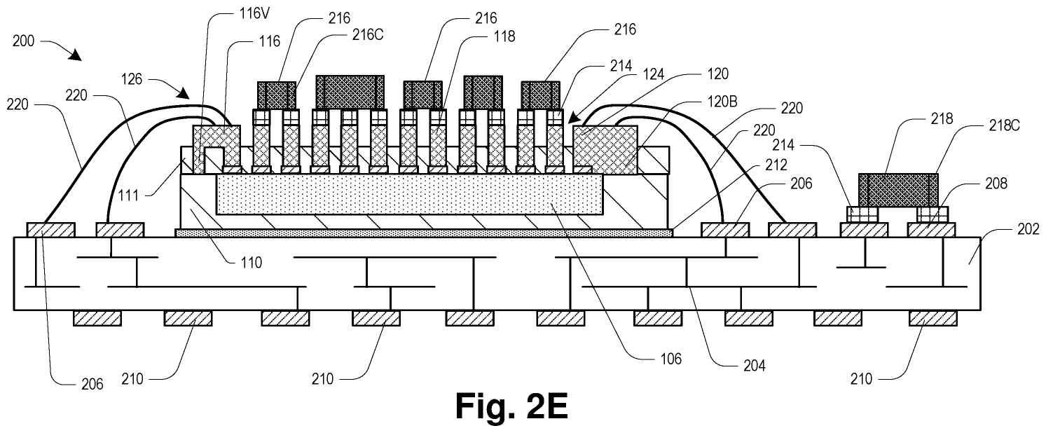

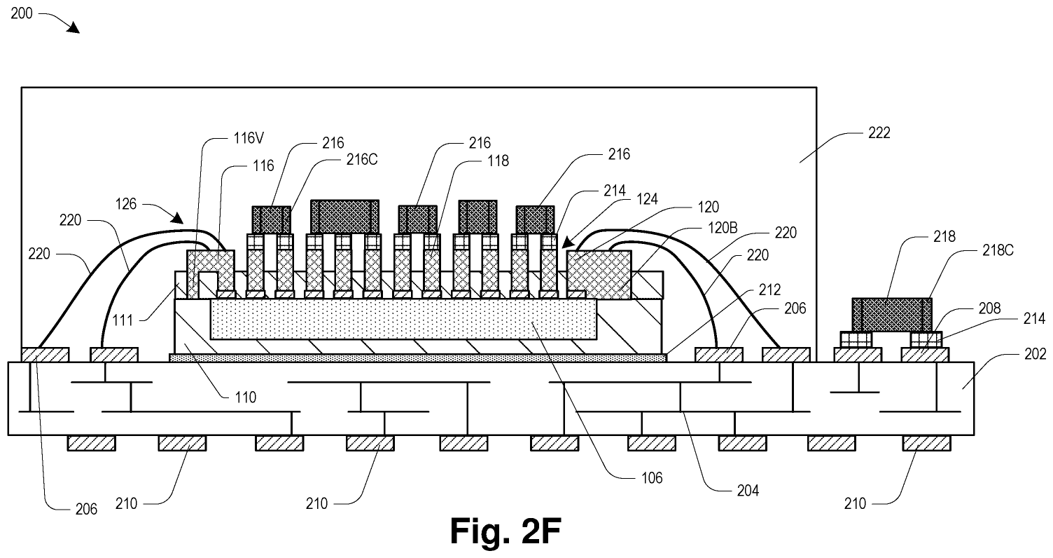

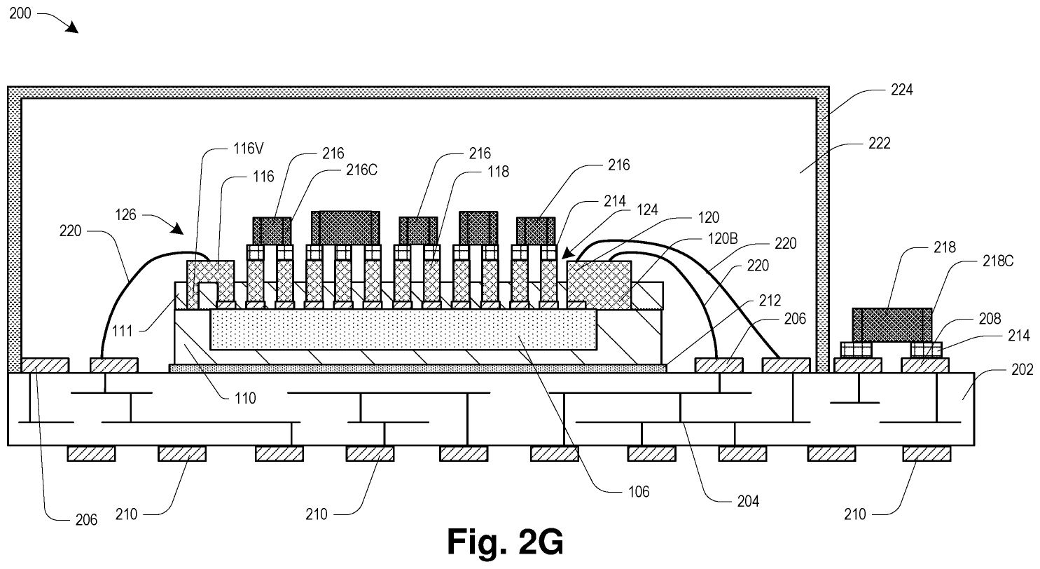

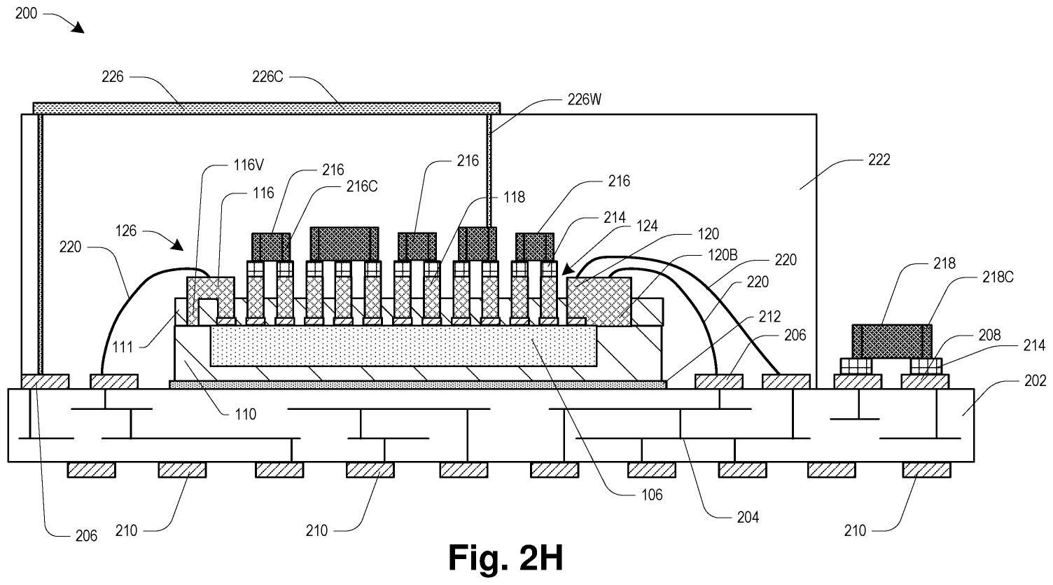

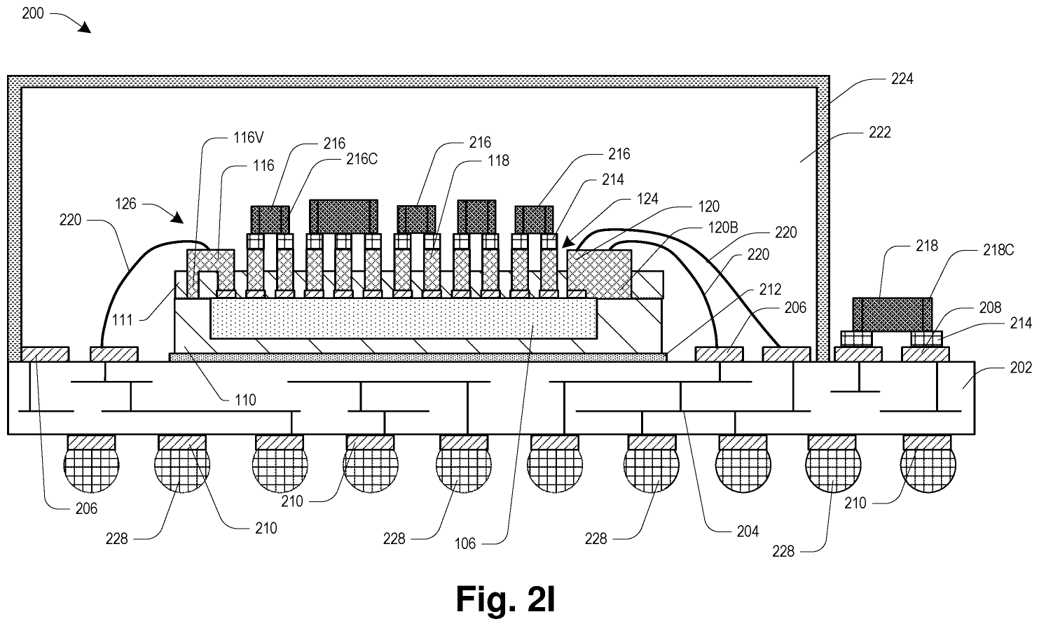

FIGS. 2A-21 are cross-section views of a device 200 during various stages of manufacturing, in accordance with some embodiments. A circuit board substrate 202 includes interconnect structures 204 and contact pads 206, 208, 210. The contact pads 206 may be located in a shielded region, the contact pads 208 may be located in a non-shielded region, and the contact pads 210 may be located in a backside region. The circuit board substrate 202 may be a laminate substrate, a molded interconnect substrate (MIS), a ceramic substrate, or some other type of substrate.

Referring to FIG. 2A, an adhesion layer 212 is formed over the circuit board substrate 202, in accordance with some embodiments. The adhesion layer 212 may be an adhesive, a solder material, an adhesive tape, or some other material.

Referring to FIG. 2B, the device pre-package 126 is mounted to the circuit board substrate 202, in accordance with some embodiments. For ease of illustration, not all elements of the device pre-package 126 are labeled. A pick and place process may be used to mount the device pre-package 126. The adhesion layer 212 may be cured.

Referring to FIG. 2C, a solder layer 214 is formed over selected portions of the redistribution layer 124 and some of the contact pads 208, in accordance with some embodiments. The solder layer 214 may comprise an SnAgCu (SAC) material, such as SAC305, or some other solder material. The solder layer 214 may be formed with solder paste using a printing, jetting, or dispensing process.

Referring to FIG. 2D, components 216, 218 are mounted to selected contact structures 118 of the redistribution layer 124 or to the contact pads 206, 208 of the circuit board substrate 202, in accordance with some embodiments. In some embodiments, the components 216, 218 are mounted using a pick and place process. The components 216 may be passive components, such as resistors, capacitors, inductors, or other passive components. The components 218 may be non-passive components, such as an antenna, a crystal, a filter, or some other non-passive components. The components 216, 218 may include contacts 216C, 218C (e.g., surface mount device (SMD) contacts, leads, or some other type of contact) that interface with the solder layer 214. A reflow process may be performed to secure the contacts 216C, 218C in the solder layer 214 on the redistribution layer 124.

Referring to FIG. 2E, wire bonds 220 are formed connecting the redistribution layer 124 to selected contact pads 206 of the circuit board substrate 202, in accordance with some embodiments. The portions 116V, 120B of the contact structures 116, 120 in the redistribution layer 124 at the wire bonding sites reduces deformation of the passivation layer 111 during the wire bonding operation, thereby improving the reliability of the wire bonding process.

Referring to FIG. 2F, a molding layer 222 is formed over the components 216, the device pre-package 126, and a portion of the circuit board substrate 202, in accordance with some embodiments. In some embodiments, the molding layer 222 does not cover the component 218 (e.g., the antenna). The molding layer 222 may comprise an epoxy molding compound.

Referring to FIG. 2G, a shielding structure 224 is formed over the molding layer 222 over at least some of the components 216, in accordance with some embodiments. The shielding structure 224 provides shielding to reduce electromagnetic interference generated by the one or more of the components 216, 218. In some embodiments, the shielding structure 224 contacts one or more of the contact pads 206 of the circuit board substrate 202 to contact a ground plane of the circuit board substrate 202 to improve the efficacy of the electromagnetic shielding for the semiconductor die 106. In some embodiments, the shielding structure 224 is formed by using a sputtering and/or electroplating process in the presence of a mask to deposit a metal material on the unmasked portion of the sputtered seed layer on the molding layer 222. In some embodiments, the shielding structure 224 comprises a metal lid that is placed over the molding layer 222 and attached to the molding layer 222, the redistribution layer 124, or the circuit board substrate 202 using an adhesive or solder connection. In an embodiment where a metal lid is used, the molding layer 222 may be omitted.

Referring to FIG. 2H, a shielding structure 226 is formed over the molding layer 222 over at least some of the components 216, in accordance with some embodiments. The shielding structure 226 comprises a wire portion 226W embedded in the molding layer 222 and a cap portion 226C formed over the molding layer 222 and contacting the wire portion 226W. The wire portion 226W may be formed by laser cutting a trench in the molding layer 222 and filling the trench with a conductive material. In another embodiment, the wire portion 226W may be formed by at least one vertical wire bond. The cap portion 226C may be formed by masked sputtering, masked plating, or printing.

Referring to FIG. 2I, solder balls 228 are formed on the backside contact pads 210, in accordance with some embodiments.

Placing the components 216 on the redistribution layer 124 reduces the horizontal footprint of the device 200. The vertical arrangement also reduces the distance between the components 216 and the semiconductor die 106, thereby increasing performance of the semiconductor die 106.

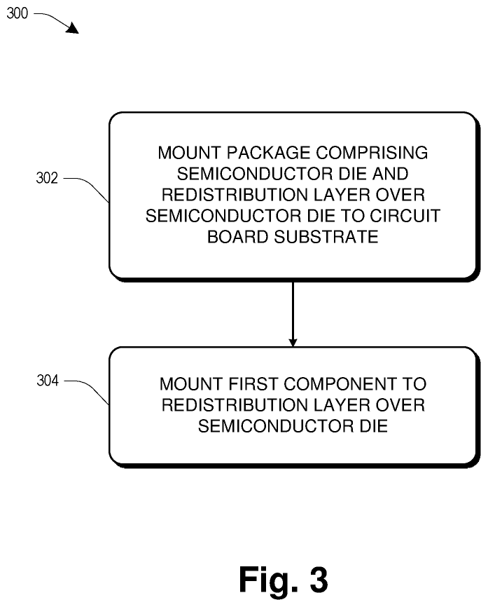

FIG. 3 is a flow diagram illustrating an example method 300 for fabricating a device 200, in accordance with some embodiments. At 302, a package comprising a semiconductor die and a redistribution layer over the semiconductor die is mounted to a circuit board substrate. At 304, a first component is mounted to the redistribution layer over the semiconductor die.

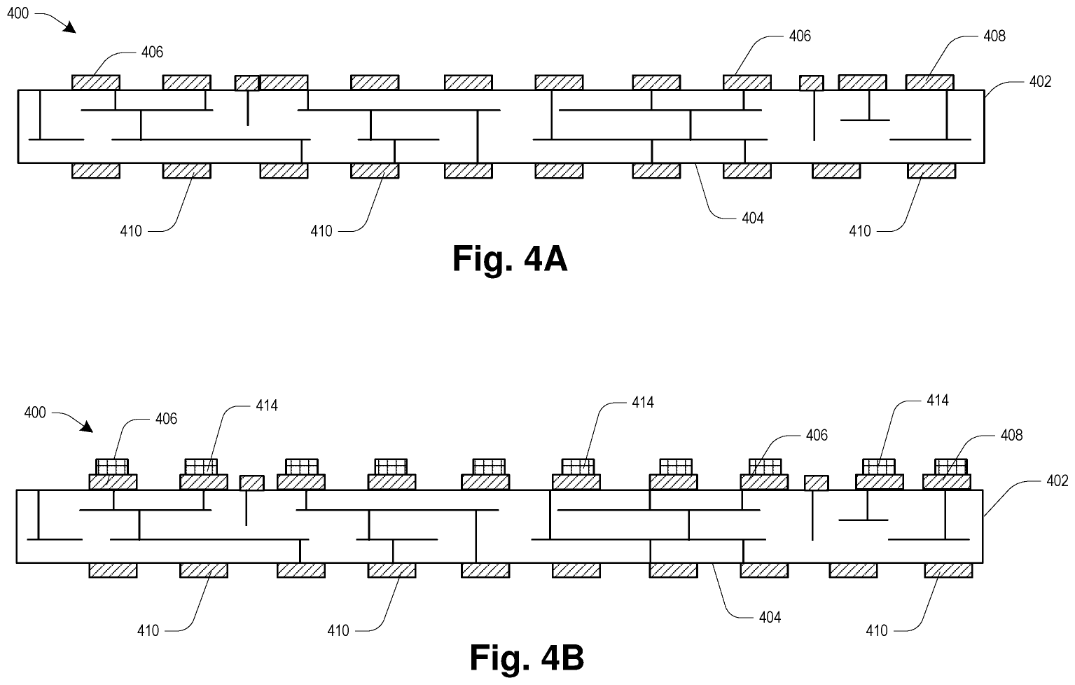

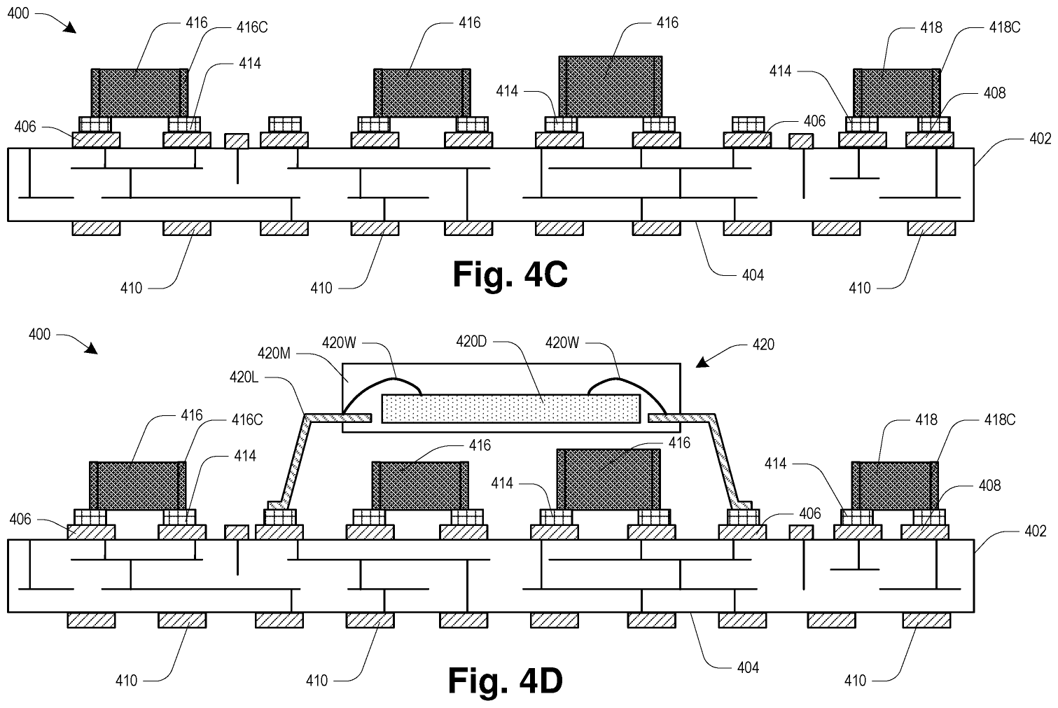

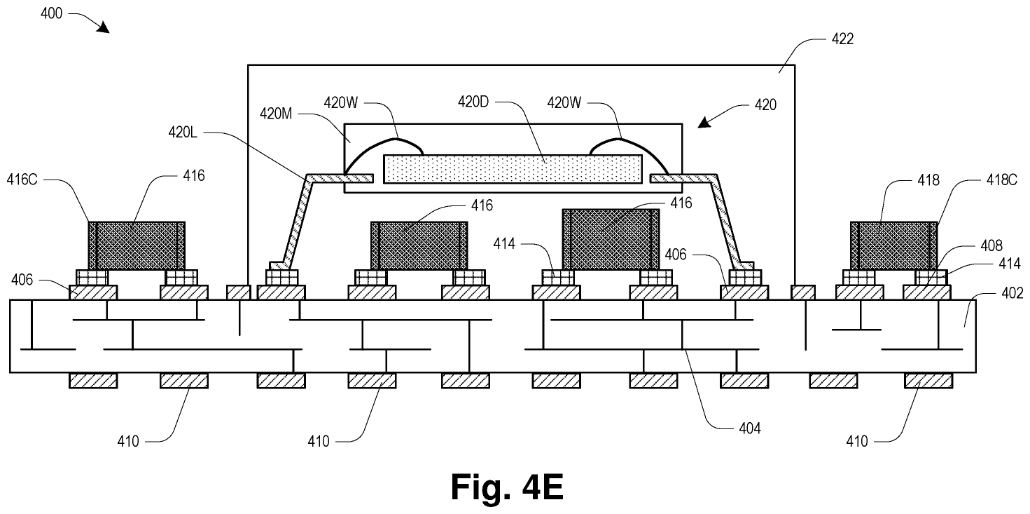

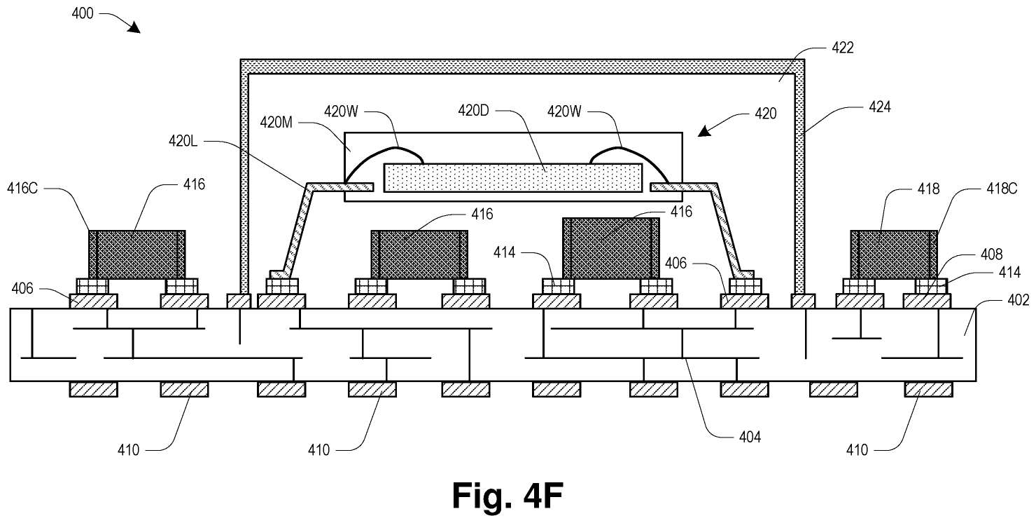

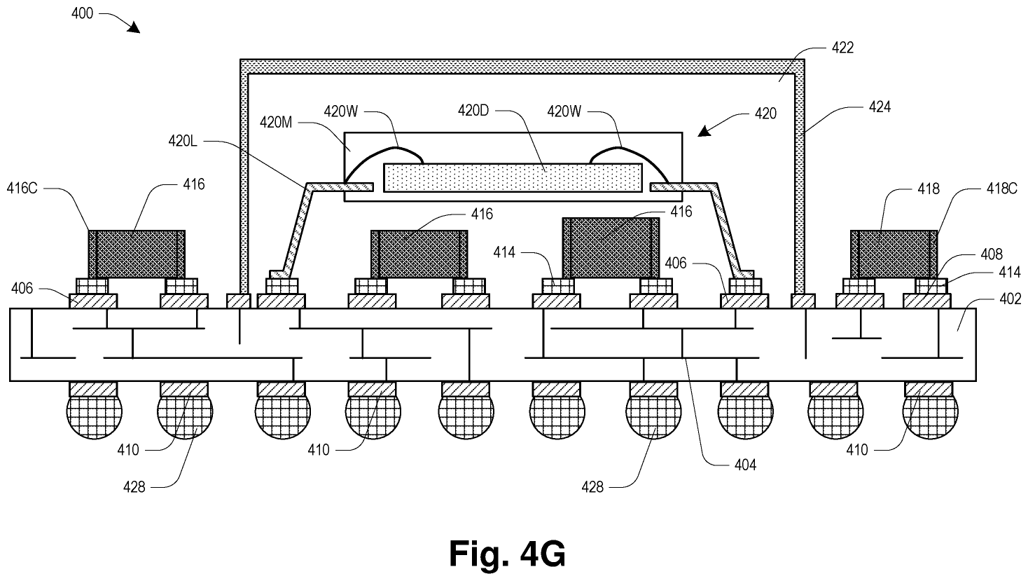

FIGS. 4A-4G are cross-section views of a device 400 during various stages of manufacturing, in accordance with some embodiments. Referring to FIG. 4A, a circuit board substrate 402 includes interconnect structures 404 and contact pads 406, 408, 410, in accordance with some embodiments. The contact pads 406 may be located in a shielded region, the contact pads 408 may be located in a non-shielded region, and the contact pads 410 may be located in a backside region. The circuit board substrate 402 may be a laminate substrate, a molded interconnect substrate (MIS), a ceramic substrate, or some other type of substrate.

Referring to FIG. 4B, a solder layer 414 is formed over selected contact pads 406, 408, in accordance with some embodiments. The solder layer 414 may comprise an SAC material, such as SAC305, or some other solder material. The solder layer 214 may be formed using a printing, jetting, or dispensing process of solder paste.

Referring to FIG. 4C, components 416, 418 are mounted to selected contact pads 406, 408 of the circuit board substrate 402, in accordance with some embodiments. In some embodiments, the components 416, 418 are mounted using a pick and place process. The components 416 may be passive components, such as resistors, capacitors, inductors, or other passive components. The components 418 may be non-passive components, such as an antenna, a crystal, a filter, or some other non-passive components. The components 416, 418 may include contacts 416C, 418C (e.g., surface mount device (SMD) contacts, leads, or some other type of contact) that interface with the solder layer 414.

Referring to FIG. 4D, a semiconductor package 420 is mounted to selected contact pads 406 of the circuit board substrate 402 over at least one of the components 416, in accordance with some embodiments. In some embodiments, the semiconductor package 420 comprises a semiconductor die 420D and extended length leads 420L. Wire bonds 420W may connect the semiconductor die 420D to the extended length leads 420L. A molding layer 420M may be formed over the semiconductor die 420D, the wire bonds 420W, and portions of the extended length leads 420L. In some embodiments, the semiconductor package 420 comprises a quad flat package with extended length leads in a lead frame that are bent during a trim and form process. In some embodiments, a common reflow process is performed to secure the contacts 416C, 418C, 420L in the solder layer 414.

Referring to FIG. 4E, a molding layer 422 is formed over the components 416, the semiconductor package 420, and a portion of the circuit board substrate 402, in accordance with some embodiments. In some embodiments, the molding layer 422 does not cover the component 418 (e.g., the antenna). The molding layer 422 may comprise an epoxy molding compound.

Referring to FIG. 4F, a shielding structure 424 is formed over the molding layer 422 over at least the semiconductor package 420 and, optionally, over some of the components 416, in accordance with some embodiments. The shielding structure 424 provides shielding to reduce electromagnetic interference generated by the one or more of the components 416, 418. In some embodiments, the shielding structure 424 contacts one or more of the contact pads 406 of the circuit board substrate 402 to contact a ground plane of the circuit board substrate 402 to improve the efficacy of the electromagnetic shielding for the semiconductor die 420D. In some embodiments, the molding layer 422 comprises a platable material and the shielding structure 424 is formed by using a sputtering and/or plating process in the presence of a mask to deposit a metal material on the unmasked portion of the molding layer 422. In some embodiments, the shielding structure 424 comprises a metal lid that is placed over the molding layer 422 and bonded to molding layer 422 or the circuit board substrate 402 using an adhesive or solder connection. In an embodiment where a metal lid is used, the molding layer 422 may be omitted.

Referring to FIG. 4G, solder balls 428 are formed on the backside contact pads 410, in accordance with some embodiments.

Placing the semiconductor package 420 over some of the components 416 reduces the horizontal footprint of the device 400. The vertical arrangement also reduces the distance between the components 416 and the semiconductor die 420D, thereby increasing performance of the semiconductor die 420D.

According to some embodiments, an apparatus, comprises a circuit board substrate, a package comprises a semiconductor die and a redistribution layer over the semiconductor die mounted to the circuit board substrate, a first component mounted to the redistribution layer over the semiconductor die, and a shielding structure mounted to the circuit board substrate over the package and the first component.

According to some embodiments, the first component comprises at least one of a resistor, a capacitor, or an inductor.

According to some embodiments, the apparatus comprises a molding layer over the package and the first component, wherein the shielding structure is over the molding layer.

According to some embodiments, the apparatus comprises a second component mounted to the circuit board substrate and not covered by the shielding structure.

According to some embodiments, the second component comprises at least one of an antenna, a crystal, or a filter.

According to some embodiments, the apparatus comprises a wire bond connected to the redistribution layer and the circuit board substrate.

According to some embodiments, the package comprises a molding layer adjacent the semiconductor die, and a passivation layer over the molding layer and the semiconductor die, wherein the redistribution layer is at least partially embedded in the passivation layer, and the redistribution layer directly contacts the molding layer under a portion of the wire bond contacting the redistribution layer.

According to some embodiments, the package comprises a molding layer adjacent the semiconductor die, and a passivation layer over the molding layer and the semiconductor die, wherein the redistribution layer is at least partially embedded in the passivation layer, the package comprises a material region embedded in the molding layer under a portion of the wire bond contacting the redistribution layer, and the material region comprises a first material stiffer than a second material of the passivation layer.

According to some embodiments, the package comprises a molding layer adjacent the semiconductor die, and a passivation layer over the molding layer and the semiconductor die, wherein the redistribution layer directly contacts the molding layer under the portion of the wire bond contacting the redistribution layer.

According to some embodiments, a package comprises a semiconductor die comprises a first contact pad, a molding layer adjacent the semiconductor die, a passivation layer over the semiconductor die and the molding layer, a redistribution layer at least partially embedded in the passivation layer and contacting the first contact pad, and a material region embedded in at least one of the passivation layer or the redistribution layer in a wire bonding site, wherein the material region comprises a first material stiffer than a second material of the passivation layer.

According to some embodiments, the material region comprises an extension of the redistribution layer.

According to some embodiments, the material region comprises at least one of a via region or a base region defined in the redistribution layer.

According to some embodiments, the material region is embedded in the molding layer and comprises at least one of silicon or a ceramic.

According to some embodiments, the passivation layer comprises polyimide.

According to some embodiments, a method, comprises mounting a package comprises a semiconductor die and a redistribution layer over the semiconductor die to a circuit board substrate, mounting a first component to the redistribution layer over the semiconductor die, and mounting a shielding structure to the circuit board substrate over the package and the first component.

According to some embodiments, mounting the first component comprises mounting at least one of a resistor, a capacitor, or an inductor to the redistribution layer over the semiconductor die.

According to some embodiments, the method comprises mounting a second component to the circuit board substrate in a region not covered by the shielding structure.

According to some embodiments, mounting the second component comprises mounting at least one of an antenna, a crystal, or a filter to the circuit board substrate in the region not covered by the shielding structure.

According to some embodiments, the method comprises embedding a material region in a molding layer of the package under the redistribution layer, and forming a wire bond between the redistribution layer and the circuit board substrate in a region of the redistribution layer over the material region, wherein the molding layer is adjacent the semiconductor die, the passivation layer is over the molding layer and the semiconductor die, the redistribution layer is at least partially embedded in the passivation layer, and the material region comprises a first material stiffer than a second material of the passivation layer.

According to some embodiments, the method comprises forming a wire bond between the redistribution layer and the circuit board substrate in a region of the redistribution layer having a portion extending through a passivation layer of the package and contacting a molding layer of the package, wherein the molding layer is adjacent the semiconductor die, the passivation layer is over the molding layer and the semiconductor die, and the redistribution layer is at least partially embedded in the passivation layer.

Various operations of embodiments are provided herein. The order in which some or all of the operations are described should not be construed as to imply that these operations are necessarily order dependent. Alternative ordering will be appreciated by one skilled in the art having the benefit of this description. Further, it will be understood that not all operations are necessarily present in each embodiment provided herein. Also, it will be understood that not all operations are necessary in some embodiments.

Any aspect or design described herein as an “example” is not necessarily to be construed as advantageous over other aspects or designs. Rather, use of the word “example” is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or more” unless specified otherwise or clear from context to be directed to a singular form. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

What is claimed is:

1. An apparatus, comprising:
a circuit board substrate;
a package comprising a semiconductor die and a redistribution layer over the semiconductor die mounted to the circuit board substrate;
a first component mounted to the redistribution layer over the semiconductor die; and
a shielding structure mounted to the circuit board substrate over the package and the first component.

2. The apparatus of claim 1, wherein:
the first component comprises at least one of a resistor, a capacitor, or an inductor.

3. The apparatus of claim 1, comprising:
a molding layer over the package and the first component, wherein the shielding structure is over the molding layer.

4. The apparatus of claim 1, comprising:
a second component mounted to the circuit board substrate and not covered by the shielding structure.

5. The apparatus of claim 4, wherein:
the second component comprises at least one of an antenna, a crystal, or a filter.

6. The apparatus of claim 1, comprising a wire bond connected to the redistribution layer and the circuit board substrate.

7. The apparatus of claim 6, wherein the package comprises a molding layer adjacent the semiconductor die, and a passivation layer over the molding layer and the semiconductor die, wherein:
the redistribution layer is at least partially embedded in the passivation layer, and
the redistribution layer directly contacts the molding layer under a portion of the wire bond contacting the redistribution layer.

8. The apparatus of claim 6, wherein the package comprises a molding layer adjacent the semiconductor die, and a passivation layer over the molding layer and the semiconductor die, wherein:
the redistribution layer is at least partially embedded in the passivation layer,
the package comprises a material region embedded in the molding layer under a portion of the wire bond contacting the redistribution layer, and
the material region comprises a first material stiffer than a second material of the passivation layer.

9. The apparatus of claim 8, wherein the package comprises a molding layer adjacent the semiconductor die, and a passivation layer over the molding layer and the semiconductor die, wherein:
the redistribution layer directly contacts the molding layer under the portion of the wire bond contacting the redistribution layer.

10. A package, comprising:
a semiconductor die comprising a first contact pad;
a molding layer adjacent the semiconductor die;
a passivation layer over the semiconductor die and the molding layer;
a redistribution layer at least partially embedded in the passivation layer and contacting the first contact pad; and
a material region embedded in at least one of the passivation layer or the redistribution layer in a wire bonding site, wherein the material region comprises a first material stiffer than a second material of the passivation layer.

11. The package of claim 10, wherein:
the material region comprises an extension of the redistribution layer.

12. The package of claim 10, wherein:
the material region comprises at least one of a via region or a base region defined in the redistribution layer.

13. The package of claim 10, wherein:
the material region is embedded in the molding layer and comprises at least one of silicon or a ceramic.

14. The package of claim 10, wherein:
the passivation layer comprises polyimide.

15. A method, comprising:
mounting a package comprising a semiconductor die and a redistribution layer over the semiconductor die to a circuit board substrate;
mounting a first component to the redistribution layer over the semiconductor die; and
mounting a shielding structure to the circuit board substrate over the package and the first component.

16. The method of claim 15, wherein mounting the first component comprises:
mounting at least one of a resistor, a capacitor, or an inductor to the redistribution layer over the semiconductor die.

17. The method of claim 15, comprising:
mounting a second component to the circuit board substrate in a region not covered by the shielding structure.

18. The method of claim 17, wherein mounting the second component comprises:
mounting at least one of an antenna, a crystal, or a filter to the circuit board substrate in the region not covered by the shielding structure.

19. The method of claim 15, comprising:
embedding a material region in a molding layer of the package under the redistribution layer; and
forming a wire bond between the redistribution layer and the circuit board substrate in a region of the redistribution layer over the material region, wherein:
the molding layer is adjacent the semiconductor die,
the passivation layer is over the molding layer and the semiconductor die,
the redistribution layer is at least partially embedded in the passivation layer, and
the material region comprises a first material stiffer than a second material of the passivation layer.

20. The method of claim 15, comprising:
forming a wire bond between the redistribution layer and the circuit board substrate in a region of the redistribution layer having a portion extending through a passivation layer of the package and contacting a molding layer of the package, wherein:
the molding layer is adjacent the semiconductor die,
the passivation layer is over the molding layer and the semiconductor die, and
the redistribution layer is at least partially embedded in the passivation layer.
